(19) United States
(12) Patent Application Publication
(10) Pub. No.: US 2026/0096225 A1
(43) Pub. Date: Apr. 2, 2026

(54) ELECTROSTATIC DISCHARGE PROTECTION DEVICE INCLUDING ELECTROSTATIC DISCHARGE MASK

(71) Applicant: DB HiTek Co., Ltd., Seoul (KR)

(72) Inventors: Bo Bae Song, Bucheon-si (KR); Young Chul Kim, Bucheon-si (KR); Jong Min Kim, Bucheon-si (KR); Seung Hyun Kim, Bucheon-si (KR); Hee Bae Lee, Bucheon-si (KR); Soon Jong Park, Bucheon-si (KR)

(21) Appl. No.: 18/966,671

(22) Filed: Dec. 3, 2024

(30) Foreign Application Priority Data
Sep. 27, 2024 (KR) 10-2024-0131550

(51) Int. Cl. H10D 89/60; H10D 62/10; H10D 62/832

(52) U.S. Cl. CPC H10D 89/811; H10D 62/124; H10D 62/8325

(57) ABSTRACT

An electrostatic discharge (ESD) protection device is proposed. The ESD protection device may include a semiconductor substrate, an epitaxial region formed on the semiconductor substrate, a well region formed on the epitaxial region, and a P⁺ diffusion region formed on the well region. The ESD protection device may also include an N⁺ diffusion region formed on the well region, an anode connected to the P⁺ diffusion region, a cathode connected to the N⁺ diffusion region, and a first ESD mask formed on the well region. P⁺ ions having predefined concentration and energy are injected through the first ESD mask.

### CROSS-REFERENCE TO RELATED APPLICATION

This application claims priority under 35 U.S.C § 119 to Korean Patent Application No. 10-2024-0131550 filed on Sep. 27, 2024, in the Korean Intellectual Property Office, the entire contents of which are hereby incorporated by reference.

### BACKGROUND

### Technical Field

The present disclosure relates to an electrostatic discharge (ESD) protection device including an ESD mask.

More specifically, the present disclosure relates to an ESD protection device that may inject high-concentration and high-energy ions through an ESD mask to cause an electrostatic discharge current to flow to a lower portion of an N⁺ diffusion region rather than a surface of the ESD protection device, thereby mitigating the generation of an electric field on the surface and further preventing damage caused by hot carriers.

### Description of Related Technology

The contents set forth in this section merely provide background information on the present embodiments and do not constitute prior art.

In general, a silicon power device uses a Zener diode formed on polysilicon (Poly-Si) to protect a gate oxide from electrostatic discharge. The Zener diode is provided in a back-to-back type according to a gate driving voltage. However, the Zener diode has a disadvantage of generating a lot of leakage current, and accordingly, there is a need to solve the leakage problem in a silicon carbide metal oxide semiconductor fiend effect transistor (SiC MOSFET) that operate at high temperature. In addition, there is not much research and development being done on diode-type devices used for electrostatic protection in the SiC MOSFET, and accordingly, there is a need to solve structural problems and improve characteristics of lateral diodes.

### SUMMARY

It is an object of the present disclosure to provide an ESD protection device capable of improving operational stability, BV, and It2.

More specifically, it is an object of the present disclosure to provide an ESD protection device that forms an ESD mask and injects high-concentration and high-energy ions P⁺ and N⁺ through the ESD mask to cause an electrostatic discharge current to flow to the bottom of an N⁺ diffusion region rather than surface of an ESD protection device, and thus, preventing an electric field from being generated on a surface and more effectively preventing damage due to hot carriers.

That is, an object of the present disclosure is to provide an ESD protection device that injects high-concentration and high-energy ions P⁺ and N⁺ through an ESD mask to cause an electrostatic discharge current to flow to a lower portion of an N⁺ diffusion region where the ESD mask is formed, rather than a lower portion of the oxide of the ESD protection device, and thus, BV may generated at a lower portion of an N⁺ diffusion region to improve It2 more effectively.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

According to some aspects of the disclosure, an electrostatic discharge (ESD) protection device comprises, a semiconductor substrate, an epitaxial region formed on the semiconductor substrate, a well region formed on the epitaxial region, a P⁺ diffusion region formed on the well region, an N⁺ diffusion region formed on the well region, an anode connected to the P⁺ diffusion region, a cathode connected to the N⁺ diffusion region, and a first ESD mask formed on the well region, wherein P⁺ ions having predefined concentration and energy are injected through the first ESD mask.

According to some aspects, the semiconductor substrate comprises a silicon carbide (SIC) wafer.

According to some aspects, the well region comprises a P⁻ type well.

According to some aspects, the first ESD mask is adjacent to the N⁺ diffusion region.

According to some aspects, the first ESD mask is formed under the N⁺ diffusion region.

According to some aspects, the first ESD mask is formed between the N⁺ diffusion region and a boundary region between the well region and the epitaxial region.

According to some aspects, the first ESD mask is formed to span across the well region and the epitaxial region.

According to some aspects of the disclosure, an electrostatic discharge (ESD) protection device comprises: a semiconductor substrate, an epitaxial region formed on the semiconductor substrate, a well region formed on the epitaxial region, a P⁺ diffusion region formed on the well region, an N⁺ diffusion region formed on the well region, an anode connected to the P⁺ diffusion region, a cathode connected to the N⁺ diffusion region, and a second ESD mask formed on the well region, wherein N+ ions having predefined concentration and energy are injected through the second ESD mask.

According to some aspects, the semiconductor substrate comprises a silicon carbide (SIC) wafer.

According to some aspects, the well region comprises a P⁻ type well.

According to some aspects, the second ESD mask is adjacent to the N⁺ diffusion region.

According to some aspects, the second ESD mask is formed under the N⁺ diffusion region.

According to some aspects, the second ESD mask is formed between the N⁺ diffusion region and a boundary region between the well region and the epitaxial region.

According to some aspects, the second ESD mask is formed to span across the well region and the epitaxial region.

According to some aspects of the disclosure, an electrostatic discharge (ESD) protection device comprises: a semiconductor substrate, an epitaxial region formed on the semiconductor substrate, a well region formed on the epitaxial region, a P⁺ diffusion region formed on the well region, an N⁺ diffusion region formed on the well region, an anode connected to the P⁺ diffusion region, a cathode connected to the N⁺ diffusion region, and a third ESD mask formed on the well region, wherein P⁺ ions and N⁺ ions, each having a predefined concentration and energy, are injected through the third ESD mask.

According to some aspects, the third ESD mask is adjacent to the N⁺ diffusion region.

According to some aspects, the third ESD mask is under the N⁺ diffusion region.

According to some aspects, the third ESD mask comprises a 3-1^{st} ESD mask into which the N⁺ ions are injected, and a 3-2^{nd} ESD mask into which the P⁺ ions are injected.

According to some aspects, the 3-1^{st} ESD mask is adjacent to the N⁺ diffusion region, and the 3-2^{nd} ESD mask is under the 3-1^{st} ESD mask.

According to some aspects, the 3-2^{nd} ESD mask is formed between the 3-1st ESD mask and a boundary region between the well region and the epitaxial region or is formed to span across the well region and the epitaxial region.

An ESD protection device according to some embodiments of the present disclosure may effectively improve operational stability, BV, and It2.

More specifically, the ESD protection device according to some embodiments of the present disclosure has a remarkable effect of more effectively preventing damage due to hot carriers by forms an ESD mask and injecting high-concentration and high-energy ions P+ and N+ through the ESD mask to cause an electrostatic discharge current to flow to the bottom of an N+ diffusion region rather than surface of an ESD protection device to prevent an electric field from being generated on a surface.

That is, the ESD protection device according to some embodiments of the present disclosure may improve It2 more effectively by injecting high-concentration and high-energy ions P+ and N+ through an ESD mask to cause an electrostatic discharge current to flow to a lower portion of an N+ diffusion region where the ESD mask is formed, rather than a lower portion of the oxide of the ESD protection device to induce generation of BV at a lower portion of an N+ diffusion region.

In addition to the above descriptions, the specific effects of the present disclosure are described together while explaining specific matters for implementing the invention below.

### BRIEF DESCRIPTION OF THE DRAWINGS

FIG. 1 is a diagram illustrating an operation of an electrostatic discharge (ESD) protection device according to some embodiments of the present disclosure.

FIG. 2 illustrates an upper portion of the ESD protection device ED according to an embodiment of the present disclosure.

FIG. 3 is a view illustrating the structure of an ESD protection device ED1 according to another embodiment of the present disclosure.

FIG. 4 is a view illustrating a structure of an ESD protection device ED2 according to another embodiment of the present disclosure.

FIG. 5 is a view illustrating a structure of an ESD protection device ED3 according to another embodiment of the present disclosure.

FIG. 6 illustrates simulation results of a conventional ESD protection device (hereinafter referred to as “ED_CV”) that does not include an ESD mask.

FIG. 7 illustrates simulation results of the first ESD protection device ED1 according to some embodiments of the present disclosure.

FIG. 8 illustrates simulation results of the third ESD protection device ED3 according to some embodiments of the present disclosure.

### DETAILED DESCRIPTION

Although current silicon-based devices use Zener diodes for electrostatic protection, the devices that operate at higher temperature, such as SiC MOSFETs, face limitations with the conventional method, and accordingly, a better protection solution and an improved diode structure are needed in relation to electrostatic prevention.

In particular, in typical ESD protection devices, a breakdown voltage (BV) of a diode is generated under the oxide, which causes structural instability. In particular, an electric field is concentrated on surfaces of these diodes, and thereby, damage occurs due to hot carriers when an ESD current flows, and there is a problem that a second breakdown current (It2) is degraded.

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

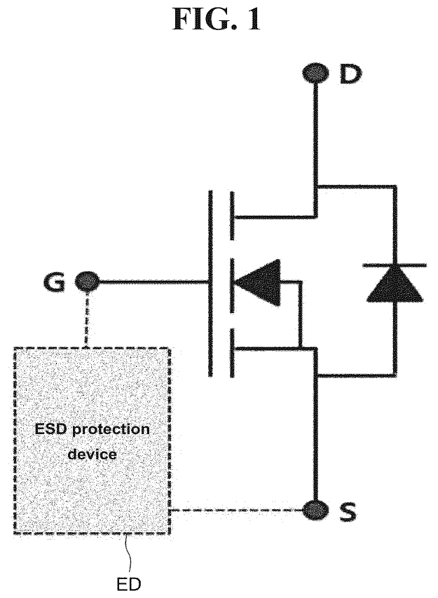

Hereinafter, an ESD protection device according to an embodiment of the present disclosure will be described with reference to FIGS. 1 to 8.

FIG. 1 is a diagram illustrating an operation of an electrostatic discharge (ESD) protection device according to some embodiments of the present disclosure.

Referring to FIG. 1, an ESD protection device (hereinafter referred to as an “ED”) according to some embodiments of the present disclosure may be included in a metal oxide semiconductor field effect transistor (MOSFET). In this case, the MOSFET may include a gate G, a source S, and a drain D as illustrated in FIG. 1. In this case, the gate G may be a control terminal of the MOSFET and may serve to control current flowing between the source S and the drain D.

The ESD protection device ED may be a device connected between the gate G and the source S to protect against electrostatic discharge. In other words, the ESD protection device ED may protect the gate G of the MOSFET from damage caused by electrostatic discharge. Since the gate G is a very sensitive portion, the gate G may be easily damaged by electrostatic discharge, and the ESD protection device ED may protect the gate G by absorbing or bypassing a discharge current. In this case, the ESD protection device ED may protect the gate G against positive or negative electrostatic charge.

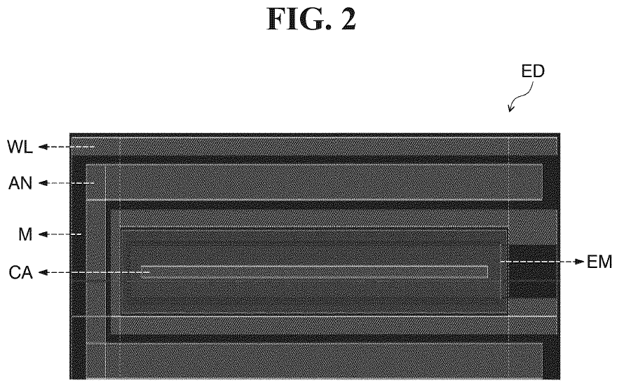

Hereinafter, a structure of the ESD protection device ED according to some embodiments of the present disclosure will be described with reference to FIGS. 2 to 5.

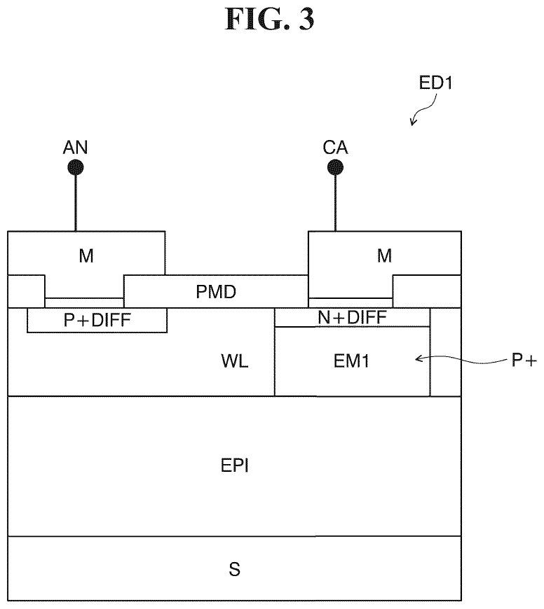

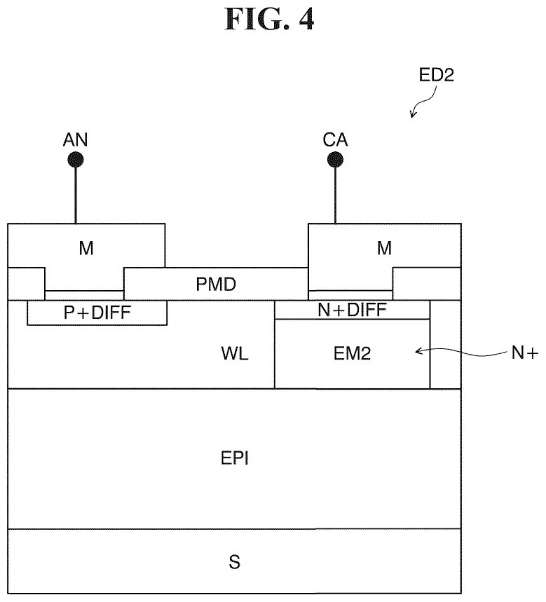

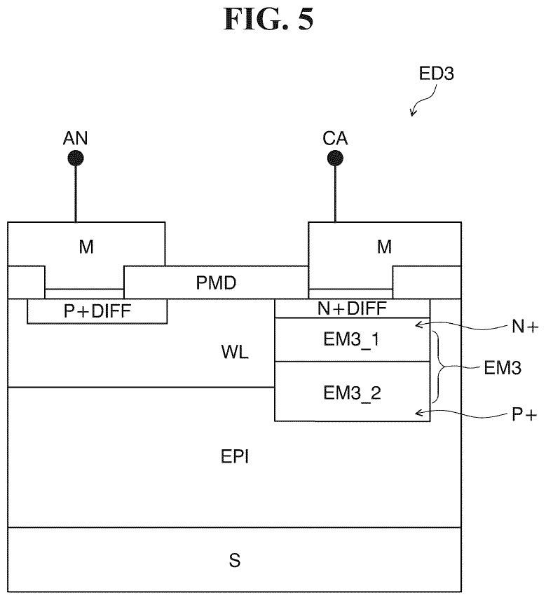

FIG. 2 illustrates an upper portion of the ESD protection device ED according to an embodiment of the present disclosure. FIG. 3 is a view illustrating the structure of an ESD protection device ED1 according to another embodiment of the present disclosure. FIG. 4 is a view illustrating a structure of an ESD protection device ED2 according to another embodiment of the present disclosure. FIG. 5 is a view illustrating a structure of an ESD protection device ED3 according to another embodiment of the present disclosure.

Referring to FIGS. 1 to 5, the ESD protection device ED according to some embodiments of the present disclosure may be divided into a first ESD protection device ED1, a second ESD protection device ED2, and a third ESD protection device ED3 depending on roles and types of ESD masks (hereinafter referred to as an “EM”), and FIGS. 3 to 5 illustrate the first ESD protection device ED1, the second ESD protection device ED2, and the third ESD protection device ED3.

Referring to FIGS. 1 to 5, the ESD protection device ED according to some embodiments of the present disclosure may include a semiconductor substrate (hereinafter referred to as “S”), an epitaxial region (hereinafter referred to as “EPI”) formed on the semiconductor substrate(S), a well region (hereinafter referred to as “WL”) formed on the epitaxial region EPI, a P+ diffusion region (hereinafter referred to as “P+DIFF”) and an N+ diffusion region (hereinafter referred to as “N+DIFF”) formed on the well region WL, an anode (hereinafter referred to as “AN”) connected to the P+ diffusion region P+DIFF, a cathode (hereinafter referred to as “CA”) connected to the N+ diffusion region N+DIFF, a metal (hereinafter referred to as “M”) disposed between the anode AN and the P+ diffusion region P+DIFF and between the cathode CA and the N+ diffusion region N+DIFF to transmit current, a pre-metal dielectric (hereinafter referred to as “PMD”) that is adjacent to the metal M, and an ESD mask EM formed on the well region WL. However, the embodiments of the present disclosure are not limited thereto, and it is obvious that some configurations may be omitted from the ESD protection device ED of the present disclosure or other configurations not illustrated may be included and implemented thereto.

The semiconductor substrate S is a component that provides a physical basis for the ESD protection device ED. In some examples, the semiconductor substrate S may include a silicon carbide wafer (Sic Wafer). In this case, the semiconductor substrate S may be an N+ substrate, but the embodiments of the present disclosure are not limited thereto.

The epitaxial region EPI is a region formed on the semiconductor substrate S. The epitaxial region EPI may provide a current path for the ESD protection device ED and may serve to promote the movement of electrons. In this case, the epitaxial region EPI may be an N− type, but the embodiments of the present disclosure are not limited thereto.

The well region WL may be a semiconductor region formed on the epitaxial region EPI. The well region WL may form a path for a current to flow or may serve to control electrical characteristics of a device. In some examples, the well region WL may include a P− type well.

The anode AN may be electrically connected to the metal M and the P+ diffusion region P+DIFF as a positive electrode. The anode AN may receive a voltage applied from the outside. The cathode CA may be electrically connected to the metal M and the N+ diffusion region N+DIFF as a negative electrode. The cathode CA may discharge a current from the ESD protection device ED. The P+ diffusion region P+DIFF is a region doped with P-impurity and transfers positive electric charges within a device. In this case, the P+ diffusion region P+DIFF may be connected to the anode AN, which is a positive electrode, to control the flow of a current on both sides. The N+ diffusion region N+DIFF is a region doped with N-impurity and transfers electrons within the device. In this case, the N+ diffusion region N+DIFF may be connected to the cathode CA which is a negative electrode. The metal M may be disposed between the anode AN and the P+ diffusion region P+DIFF and between the cathode CA and the N+ diffusion region N+DIFF to transfer a current. The insulating layer PMD is an insulating film between the metals M and may prevent electrical interference between metal M electrodes. The insulating layer PMD may protect the metal M electrodes from being electrically connected to each other.

The ESD mask EM may be formed on the well region WL. In this case, the ESD mask EM may move a current path downward to form a deep current path. In this case, high-concentration and high-energy ions may be injected through the ESD mask EM. In other words, high-concentration and high-energy ion implant (high doping & high energy ion implant) may be performed through the ESD mask EM. In this case, the ions injected through the ESD mask EM may include P+ ions and/or N+ ions.

In some examples, the ESD mask EM may include a first ESD mask EM1, a second ESD mask EM2, and a third ESD mask EM3 as described above.

More specifically, referring to FIGS. 1 to 3, the first ESD protection device ED1 may include the first ESD mask EM1. In this case, high-concentration and high-energy P+ ions may be injected through the first ESD mask EM1. In other words, the first ESD mask EM1 may serve as a passage that allows high-concentration and high-energy P+ ions to be injected.

In some examples, the first ESD mask EM1 may be disposed, located, and formed at a position that is adjacent to the N+ diffusion region N+DIFF on the well region WL. In other words, the first ESD mask EM1 may be formed to be adjacent to the N+ diffusion region N+DIFF on the well region WL.

For example, the first ESD mask EM1 may be formed under the N+diffusion region N+DIFF on the well region WL. In other words, a separation distance between the first ESD mask EM1 and the epitaxial region EPI may be less than a separation distance between the N+ diffusion region N+DIFF and the epitaxial region EPI.

For example, the first ESD mask EM1 may be formed between the N+diffusion region N+DIFF and the boundary region between the well region WL and the epitaxial region EPI. For example, as illustrated in FIG. 3, a first surface of the first ESD mask EM1 may be in contact with the N+ diffusion region N+DIFF, and a second surface of the first ESD mask EM1 may be in contact with the epitaxial region EPI.

In another example, the first ESD mask EM1 may be in contact with the well region WL and the epitaxial region EPI. For example, the first surface of the first ESD mask EM1 may be disposed to be adjacent to the N+ diffusion region N+DIFF, and the second surface of the first ESD mask EM1 may be in contact with a part of the epitaxial region EPI.

In contrast to this, referring to FIGS. 1, 2, and 4, the second ESD protection device ED2 may include the second ESD mask EM2. In this case, high-concentration and high-energy N+ ions may be injected through the second ESD mask EM2. In other words, the second ESD mask EM2 may serve as a passage that allows the high-concentration and high-energy N+ ions to be injected.

In some examples, the second ESD mask EM2 may be disposed, located, and formed at a position that is adjacent to the N+ diffusion region N+DIFF on the well region WL. In other words, the second ESD mask EM2 may be adjacent to the N+ diffusion region N+DIFF on the well region WL.

For example, the second ESD mask EM2 may be formed under the N+diffusion region N+DIFF on the well region WL. In other words, a separation distance between the second ESD mask EM2 and the epitaxial region EPI may be less than a separation distance between the N+ diffusion region N+DIFF and the epitaxial region EPI.

In one example, the second ESD mask EM2 may be formed between the N+ diffusion region N+DIFF and a boundary region between the well region WL and the epitaxial region EPI. For example, as illustrated in FIG. 4, the first surface of the second ESD mask EM2 may be in contact with the N+ diffusion region N+DIFF, and the second surface of the second ESD mask EM2 may be in contact with the epitaxial region EPI.

In another example, the second ESD mask EM2 may be in contact with the well region WL and the epitaxial region EPI. For example, the first surface of the second ESD mask EM2 may be adjacent to the N+ diffusion region (N+DIFF), and the second surface of the second ESD mask EM2 may be located on a part of the epitaxial region EPI.

In contrast to this, referring to FIGS. 1, 2, and 5, the third ESD protection device ED3 may include the third ESD mask EM3. In this case, high-concentration and high-energy P+ ions and N+ ions may be injected through the third ESD mask EM3. In other words, the third ESD mask EM3 may serve as a passage that allows the high-concentration and high-energy P+ ions and N+ ions to be injected.

For example, the third ESD mask EM3 may include a 3-1st ESD mask EM3_1 and a 3-2nd ESD mask EM3_2. In this case, high-concentration and high-energy N+ ions may be injected through the 3-1st ESD mask EM3_1, and high-concentration and high-energy P+ ions may be injected through the 3-2nd ESD mask EM3_2.

In this case, the 3-1st ESD mask EM3_1 may be disposed, located, and formed on the 3-2nd ESD mask EM3_2. That is, a position where the high-concentration and high-energy N+ ions are injected may be a position that is adjacent to the N+ diffusion region N+DIFF than a position where the high-concentration and high-energy P+ ions are injected.

For example, the 3-1st ESD mask EM3_1 may be in contact with the N+ diffusion region N+DIFF, and the 3-2nd ESD mask EM3_2 may be in contact with a lower portion of the 3-1st ESD mask EM3_1.

For example, the 3-2nd ESD mask EM3_2 may be formed between the 3-1st ESD mask EM3_1 and a boundary region between the well region WL and the epitaxial region EPI. For example, a first surface of the 3-2nd ESD mask EM3_2 may be in contact with a lower surface of the 3-1 ESD mask EM3_1, and a second surface of the 3-2nd ESD mask EM3_2 may be in contact with the epitaxial region EPI.

In another example, the 3-2nd ESD mask EM3_2 may be in contact with the well region WL and the epitaxial region EPI. For example, as illustrated in FIG. 5, the first surface of the 3-2nd ESD mask EM3_2 may be in contact with a lower surface of the 3-1 ESD mask EM3_1, and the second surface of the 3-2nd ESD mask EM3_2 may be located on a part of the epitaxial region EPI. In this case, when the 3-2nd ESD mask EM3_2 is in contact with the well region WL and the epitaxial region EPI, an area occupied by the ESD mask EM increases, and thus, a current distribution effect may be further increased.

Referring back to FIGS. 1 to 5, through the ESD mask EM according to some embodiments of the present disclosure, a current path may be moved to a lower portion of the N+ diffusion region N+DIFF instead of a lower portion of the oxide (for example, a lower portion of the insulating film PMD), that is a position where the ESD mask EM is located, and accordingly, a deep current path may be formed, and therethrough, a position where the breakdown voltage is generated may be moved to a lower portion, and thus, It2 may be effectively improved.

That is, by injecting high-concentration and high-energy ions P+ and N+ through the ESD mask EM according to some embodiments of the present disclosure, the electrostatic discharge current may flow to a lower portion of the N+ diffusion region N+DIFF instead of a surface of the ESD protection device ED, and accordingly, an electric field may be prevented from being generated on a surface and there is a remarkable effect of more effectively preventing damage due to hot carriers.

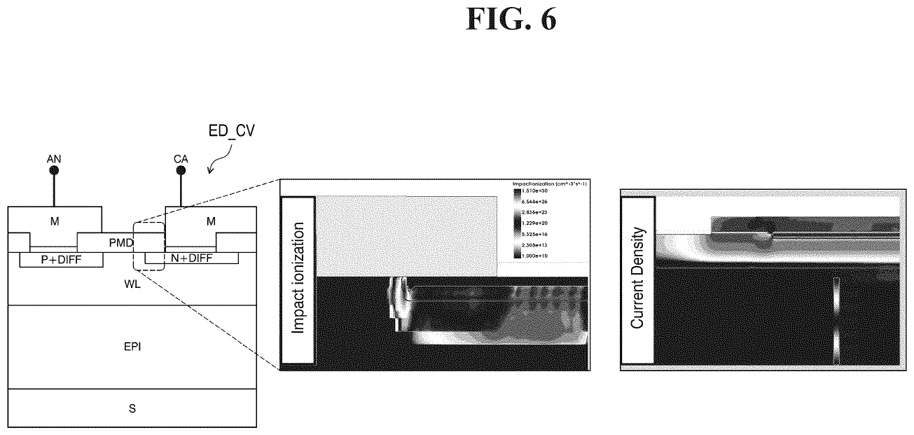

Hereinafter, simulation results related to an effect of the ESD protection device ED according to some embodiments of the present disclosure will be described with reference to FIGS. 6 to 8.

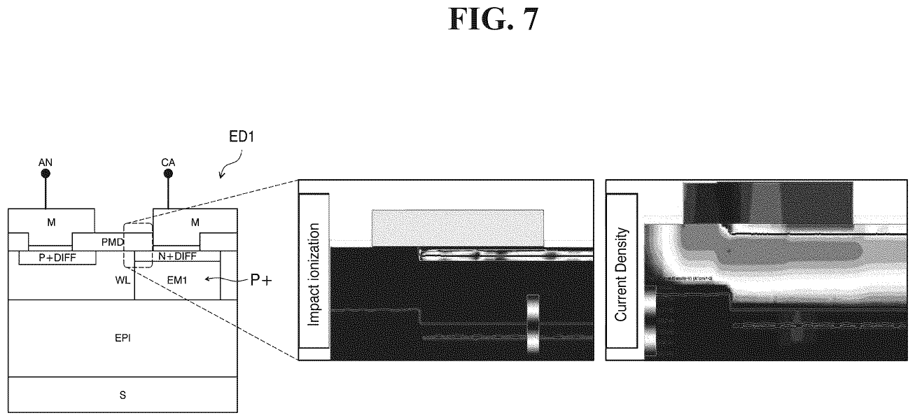

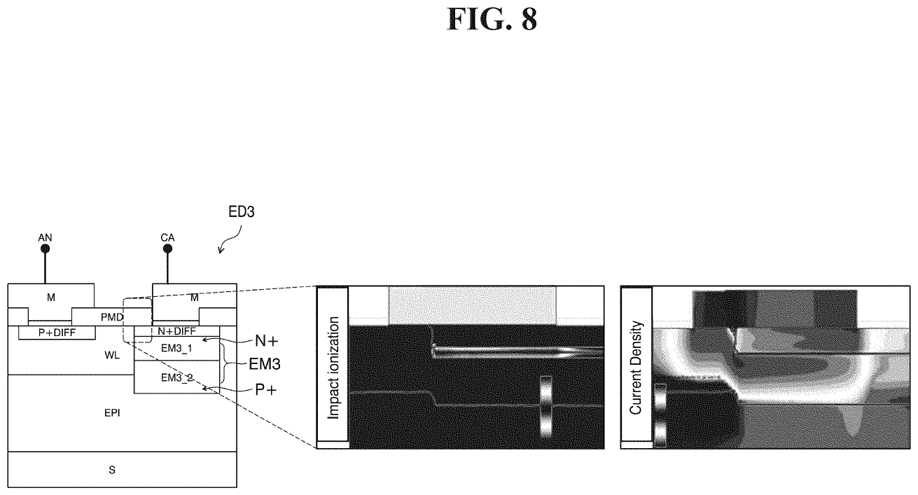

FIGS. 6 to 8 illustrate the simulation results representing the effect of the ESD protection device ED according to some embodiments of the present disclosure. FIG. 6 illustrates simulation results of a conventional ESD protection device (hereinafter referred to as “ED_CV”) that does not include an ESD mask, FIG. 7 illustrates simulation results of the first ESD protection device ED1 according to some embodiments of the present disclosure, and FIG. 8 illustrates simulation results of the third ESD protection device ED3 according to some embodiments of the present disclosure.

Referring to FIG. 6, FIG. 6 illustrates a simulation result related to impact ionization and a simulation result related to current density based on positions of an insulating layer PMD and an N+ diffusion region N+DIFF of the conventional ESD protection device ED_CV. Referring to the simulation result related to the impact ionization of FIG. 6, it can be seen that ionization is concentrated under an oxide (the insulating layer PMD) and a high electric field is formed. That is, it can be seen that a BV generation region is under the oxide and above the N+ diffusion region N+DIFF. In addition, referring to the simulation result related to the current density of FIG. 6, it can be seen that most of the current flows through the N+ diffusion region N+DIFF. In this case, the electric field is concentrated on a surface, and accordingly, It2 may deteriorate due to damage caused by hot carriers.

Referring to FIG. 7, FIG. 7 illustrates a simulation result related to impact ionization and a simulation result related to current density based on positions of the insulating layer PMD and the N+ diffusion region N+DIFF of the first ESD protection device ED1 according to some embodiments of the present disclosure. Comparing the simulation result related to impact ionization of FIG. 6 with the simulation result related to impact ionization of FIG. 7, it can be seen that the phenomenon is alleviated in which ionization is concentrated under an oxide (the insulating layer PMD) of the first ESD protection device ED1 according to some embodiments of the present disclosure and the BV generation region is a lower portion of the N+ diffusion region N+DIFF. Comparing the simulation result related to the current density of FIG. 6 with the simulation result related to the current density of FIG. 7, it can be seen that a surface electric field under the oxide (the insulating layer PMD) of the first ESD protection device ED1 according to some embodiments of the present disclosure is reduced, and thus, damage due to hot carriers may be prevented.

Referring to FIG. 8, FIG. 8 illustrates simulation results related to impact ionization and current density based on positions of the insulating layer PMD and the N+ diffusion region N+DIFF of the third ESD protection device ED3 according to some embodiments of the present disclosure. Comparing the simulation result related to impact ionization of FIG. 6 with the simulation result related to impact ionization of FIG. 8, it can be seen that a phenomenon is alleviated in which ionization is concentrated under an oxide (the insulating layer PMD) of the third ESD protection device ED3 according to some embodiments of the present disclosure and a BV generation region is a lower portion of the N+ diffusion region N+DIFF. In this case, the 3-2nd ESD mask EM3_2 of the third ESD protection device ED3 is in contact with the well region WL and the epitaxial region EPI, and accordingly, it can be seen that the BV generation region is further separated from the lower portion of the oxide (the insulating layer PMD). Comparing the simulation result related to current density of FIG. 6 with the simulation result related to current density of FIG. 8, it can be seen that a surface electric field reduced at a lower portion of an oxide layer (the insulating layer PMD) of the third ESD protection device ED3 according to some embodiments of the present disclosure, and thus damage due to hot carriers may be prevented. In this case, it can be seen that a current dissipation effect may be further increased because the 3-2nd ESD mask EM3_2 of the third ESD protection device ED3 is in contact with the well region WL and the epitaxial region EPI.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. An electrostatic discharge (ESD) protection device comprising:
a semiconductor substrate;
an epitaxial region formed on the semiconductor substrate;
a well region formed on the epitaxial region;
a P⁺ diffusion region formed on the well region;
an N⁺ diffusion region formed on the well region;
an anode connected to the P⁺ diffusion region;
a cathode connected to the N⁺ diffusion region; and
a first ESD mask formed on the well region,
wherein P⁺ ions having predefined concentration and energy are injected through the first ESD mask.

2. The ESD protection device of claim 1, wherein the semiconductor substrate comprises a silicon carbide (SIC) wafer.

3. The ESD protection device of claim 1, wherein the well region comprises a P− type well.

4. The ESD protection device of claim 1, wherein the first ESD mask is adjacent to the N⁺ diffusion region.

5. The ESD protection device of claim 4, wherein the first ESD mask is formed under the N⁺ diffusion region.

6. The ESD protection device of claim 5, wherein the first ESD mask is formed between the N⁺ diffusion region and a boundary region between the well region and the epitaxial region.

7. The ESD protection device of claim 5, wherein the first ESD mask is formed to span across the well region and the epitaxial region.

8. An electrostatic discharge (ESD) protection device comprising:
a semiconductor substrate;
an epitaxial region formed on the semiconductor substrate;
a well region formed on the epitaxial region;
a P⁺ diffusion region formed on the well region;
an N⁺ diffusion region formed on the well region;
an anode connected to the P⁺ diffusion region;
a cathode connected to the N⁺ diffusion region; and
a second ESD mask formed on the well region,
wherein N⁺ ions having predefined concentration and energy are configured to be injected through the second ESD mask.

9. The ESD protection device of claim 8, wherein the semiconductor substrate comprises a silicon carbide (SIC) wafer.

10. The ESD protection device of claim 8, wherein the well region comprises a P− type well.

11. The ESD protection device of claim 8, wherein the second ESD mask is adjacent to the N⁺ diffusion region.

12. The ESD protection device of claim 11, wherein the second ESD mask is formed under the N⁺ diffusion region.

13. The ESD protection device of claim 12, wherein the second ESD mask is formed between the N⁺ diffusion region and a boundary region between the well region and the epitaxial region.

14. The ESD protection device of claim 12, wherein the second ESD mask is formed to span across the well region and the epitaxial region.

15. An electrostatic discharge (ESD) protection device comprising:
a semiconductor substrate;
an epitaxial region formed on the semiconductor substrate;
a well region formed on the epitaxial region;
a P⁺ diffusion region formed on the well region;
an N⁺ diffusion region formed on the well region;
an anode connected to the P⁺ diffusion region;
a cathode connected to the N⁺ diffusion region; and
a third ESD mask formed on the well region,
wherein P⁺ ions and N⁺ ions, each having a predefined concentration and energy, are configured to be injected through the third ESD mask.

16. The ESD protection device of claim 15, wherein the third ESD mask is adjacent to the N⁺ diffusion region.

17. The ESD protection device of claim 15, wherein the third ESD mask is under the N⁺ diffusion region.

18. The ESD protection device of claim 15, wherein the third ESD mask comprises a 3-1^{st} ESD mask into which the N⁺ ions are injected, and a 3-2^{nd} ESD mask into which the P⁺ ions are injected.

19. The ESD protection device of claim 18, wherein the 3-1^{st} ESD mask is adjacent to the N⁺ diffusion region, and the 3-2^{nd} ESD mask is under the 3-1^{st} ESD mask.

20. The ESD protection device of claim 19, wherein the 3-2^{nd} ESD mask is formed between the 3-1^{st} ESD mask and a boundary region between the well region and the epitaxial region or is formed to span across the well region and the epitaxial region.
